(19) United States
(12) Patent Application Publication
(10) Pub. No.: US 2022/0318205 A1
(43) Pub. Date: Oct. 6, 2022

(54) MACHINE STATION FILE PROCESSING METHODS AND MACHINE STATION FILE PROCESSING SYSTEMS

(71) Applicant: CHANGXIN MEMORY TECHNOLOGIES, INC., Hefei, Anhui (CN)

(72) Inventors: Hui ZHANG, Hefei, (CN); Hanxu GAO, Hefei, (CN)

(73) Assignee: CHANGXIN MEMORY TECHNOLOGIES, INC., Hefei, Anhui (CN)

(21) Appl. No.: 17/310,355

(22) PCT Filed: Feb. 9, 2021
(86) PCT No.: PCT/CN2021/076330

§ 371 Date: Jul. 28, 2021

(30) Foreign Application Priority Data
Feb. 24, 2020 (CN) 202010113609.5

(51) Int. Cl. G06F 16/17; G06F 16/178; G06F 16/18

(52) U.S. Cl. CPC G06F 16/1734; G06F 16/178; G06F 16/1865

(57) ABSTRACT

A machine station file processing method includes: monitoring operation of a file system of a machine station server and acquiring a transaction file generated by the operation, the transaction file comprising transaction data; converting a format of the transaction data according to preset warehousing rules to generate model-layer data; and sending, to a data warehouse server, the model-layer data and a data analysis request, the data analysis request is used to instruct the data warehouse server to acquire application-layer data according to the model-layer data.

### CROSS-REFERENCE TO RELATED APPLICATIONS

The present disclosure claims the priority to the Chinese patent application 202010113609.5, titled “MACHINE STATION FILE PROCESSING METHODS AND MACHINE STATION FILE PROCESSING SYSTEMS”, and filed on Feb. 24, 2020, which is incorporated herein by reference in its entirety.

### TECHNICAL FIELD

The present disclosure relates to a machine station file processing method and a machine station file processing system.

### BACKGROUND

As the demand for chips from terminal devices such as mobile phones and computers continues to increase, in the field of semiconductors, manufacturing devices and testing devices for chips are further upgraded, which correspondingly shortens the chip production and test periods. Therefore, in order to acquire the test results of wafers and chips faster and more intuitively, higher requirements for the processing speed and accuracy of the test files produced by the machine station have been proposed.

In the prior art , the commonly used test file processing method in the industry is to manually export the test files out of the machine station and then generate relevant analysis data of wafers by EXCEL macros.

### SUMMARY

According to various embodiments, the present disclosure provides a machine station file processing method, applied to an edge computing server, comprising:

monitoring operation of a file system of a machine station server and acquiring a transaction file generated by the operation, the transaction file comprising transaction data;

converting a format of the transaction data according to preset warehousing rules to generate model-layer data; and

sending, to a data warehouse server, the model-layer data and a data analysis request, the data analysis request is used to instruct the data warehouse server to acquire application-layer data according to the model-layer data.

According to various embodiments, the present disclosure further provides a machine station file processing method, applied to a machine station file processing system comprising a data warehouse server, the machine station file processing method comprises:

controlling the data warehouse server to:

receive model-layer data and a data analysis request sent by an edge computing server; and

acquire a data field required to be output and convert a format of the model-layer data according to the data field to generate application-layer data, the application-layer data being used to generate a visual page.

According to various embodiments, the present disclosure further provides a machine station file processing system, comprising:

an edge computing server, configured to monitor operation of a file system of a machine station server and acquire a transaction file generated by the operation; convert a format of the transaction data according to preset warehousing rules, to generate model-layer data; and send, to a data warehouse server, the model-layer data and a data analysis request, the data analysis request is used to instruct the data warehouse server to acquire application-layer data according to the model-layer data; and

a data warehouse server, configured to receive the model-level data and the data analysis request sent by an edge computing server; and acquire a data field required to be output and convert the format of the model-layer data according to the data field to generate the application-layer data.

The details of one or more embodiments of the present disclosure are set forth in the following drawings and description. Other features and advantages of the present disclosure will become apparent from the description, drawings and claims.

### BRIEF DESCRIPTION OF THE DRAWINGS

In order to explain technical solutions of embodiments of the present disclosure or in the prior art more clearly, the drawings to be used for describing the embodiments or the prior art will be introduced simply. Apparently, the drawings to be described below are merely some embodiments of the present disclosure, and a person of ordinary skill in the art may further obtain other drawings according to these drawings without paying any creative effort.

FIG. 1 is a flowchart of a machine station file processing method in an embodiment;

FIG. 2 is a screenshot of transaction data in an embodiment;

FIG. 3 is a screenshot of model-layer data in an embodiment;

FIG. 4 is a screenshot of application-layer data in an embodiment;

FIG. 5 is a sub-flowchart of S100 in an embodiment;

FIG. 6 is a sub-flowchart of S200 in an embodiment;

FIG. 7 is a sub-flowchart of S230 to S240 in an embodiment;

FIG. 8 is a sub-flowchart of S200 in another embodiment;

FIG. 9 is a flowchart of a machine station file processing method in another embodiment;

FIG. 10 is a visual page of a wafer map in an embodiment;

FIG. 11 is a flowchart of a machine station file processing method in still another embodiment;

FIG. 12 is a flowchart of a machine station file processing method in yet another embodiment;

FIG. 13 is a schematic structure diagram of a machine station file processing system in an embodiment;

FIG. 14 is a schematic structure diagram of a machine station file processing system in another embodiment; and

FIG. 15 is a schematic structure diagram of an edge computing server in an embodiment.

### DESCRIPTION OF THE EMBODIMENTS

Data can be generated by manual operation. However, on one hand, by manually exporting, the newly generated test files cannot be acquired in time, and the files are exported slowly; and on the other hand, when data is manually processed, different EXCEL macros may be needed for different machines station, and only one file can be processed at a time. Therefore, the present processing method cannot meet the industry's demand for the timeliness of machine station file processing.

In order to facilitate the understanding of the present disclosure, the present disclosure will be described more fully below with reference to the relevant drawings. Preferred embodiments of the present disclosure are shown in the drawings. However, the present disclosure may be implemented in many different forms and is not limited to the embodiments described herein. On the contrary, these embodiments are provided to make the disclosure of the present disclosure more thorough and comprehensive.

Unless otherwise defined, all technical and scientific terms used herein have the same meaning as commonly understood by a person of ordinary skill in the art to which the present disclosure belongs. Here, terms used in the description of the present disclosure are merely intended to describe specific embodiments, rather than limiting the present disclosure. As used herein, the term “and/or” includes any or all of one or more associated listed items or combinations thereof.

In the description of the present disclosure, it should be understood that orientations or positional relationships indicated by terms such as “upper”, “lower”, “vertical”, “horizontal”, “inner”, “outer” are the orientations and the positional relationships illustrated on the basis of the drawings, and used just for convenience of describing the present disclosure and simplifying the description, rather than indicating or implying that the devices or elements must have a specific orientation and be constructed and operated in the specific orientation, and therefore shall not be considered as any limitations to the present disclosure.

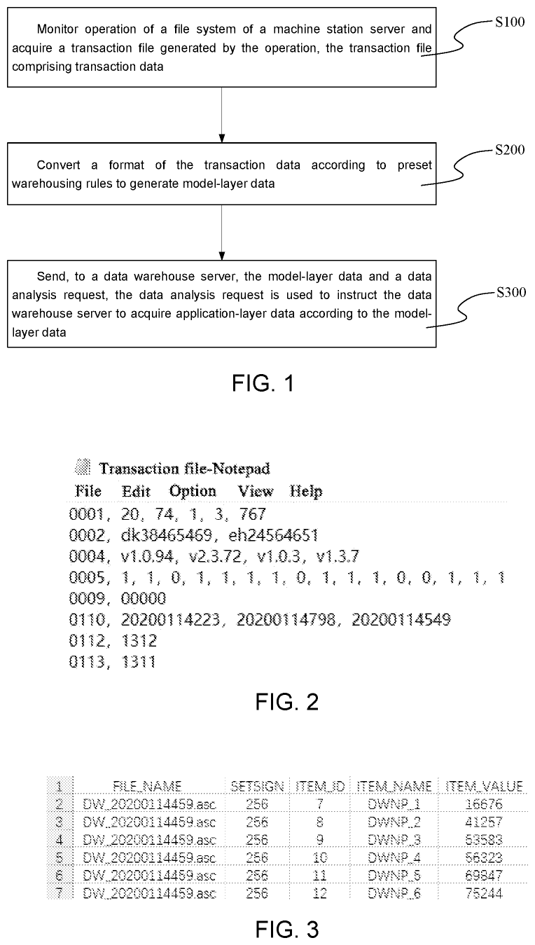

FIG. 1 is a flowchart of a machine station file processing method in an embodiment. The machine station file processing method in this embodiment is applied to an edge computing server. As shown in FIG. 1, the machine station file processing method in this embodiment comprises S100 to S300.

S100: The operation of a file system of a machine server is monitored and a transaction file generated by the operation is acquired, the transaction file comprising transaction data.

Wherein, the machine station server comprises a WP machine station server, a TM machine station server, etc. Different machine stations are used to acquire test data at different stages of wafer process or in different characterization methods. The different characterization methods comprise optical tests, electrical tests, etc. The addition, modification, and deletion of files are all operations of the file system, but only the addition and modification operations will generate transaction files. Therefore, the machine station file processing method in this embodiment focuses on only the addition and modification operations. The transaction data is the data saved in the transaction files.

Specifically, when the machine station server tests a new wafer, an added transaction file will be generated; and when the machine station server repeats the test on the tested wafer, a modified transaction file will be generated. The generation of transaction files must be accompanied by corresponding operations. Therefore, by monitoring the addition or modification operation of the file system, it may be found that transaction files have been generated on the machine station server. In this way, the transaction files may be sent to the edge computing server in time.

FIG. 2 is a screenshot of transaction data in an embodiment. As shown in FIG. 2, a transaction file usually comprises multiple lines of transaction data. In this embodiment, lines of transaction data contain different data formats and data volumes. It is unable for the operator to know the test result of a wafer only by the transaction file. Therefore, it is necessary to process the data in the transaction file to obtain the intuitive test result.

S200: The format of the transaction data is converted according to preset warehousing rules to generate model-layer data.

Wherein, the preset warehousing rules are rules that have been set in the edge computing server for different machine station servers, and the preset warehousing rules comprise conditions and methods for format conversion of the transaction data. The model-layer data is data that can be directly analyzed.

Specifically, there is difference in the definition of the format, unit, naming, etc., of the transaction files generated by different machine stations. For example, to determine whether the thickness of a set layer of a wafer meets a thickness threshold, some machine stations are recorded in 0 and 1 while the other machine stations are recorded in YES and NO. For another example, to record the width of lines, micrometer is used as the unit in some machine stations while nanometer is used as the unit in the other machine stations. Therefore, it is unable to efficiently analyze the transaction files generated by different machine stations only by a same data analysis method. FIG. 3 is a screenshot of model-layer data in an embodiment. As shown in FIG. 3, the model-layer data is clear in structure, and transaction files generated by different machine stations can be converted into model-layer data with the same definition of the format, unit, naming, etc. Therefore, during data analysis, the test results of different wafer demand parameters may be obtained simply and quickly from the model-layer data according to the needs of data analysis. In this embodiment, unstructured transaction data is converted into structured model-layer data by a format conversion operation, which reduces the complexity of data analysis, thereby improving the efficiency of data analysis.

S300: The model-layer data and a data analysis request are sent to a data warehouse server. The data analysis request is used to instruct the data warehouse server to acquire application-layer data according to the model-layer data.

Wherein, the application-layer data is the data required by the business generated after handling and processing. That is, the application-layer data contains less data, and the data that does not need to be displayed and applied has been eliminated.

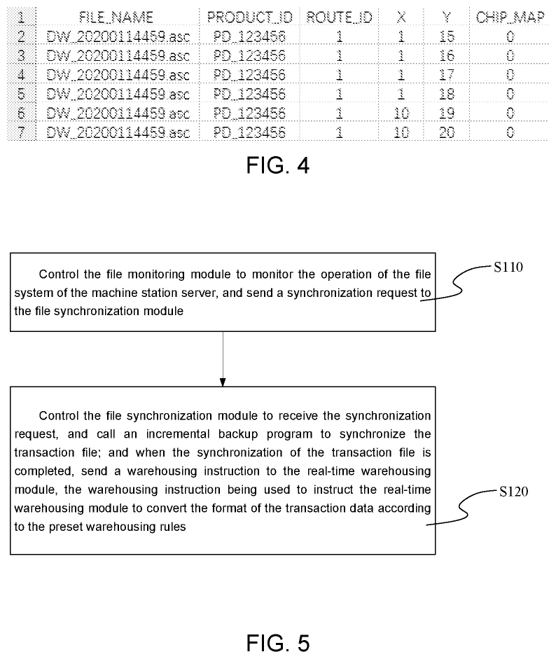

Specifically, the edge computing server synchronously sends the generated model-layer data and the data analysis request to the data warehouse server, and the data warehouse server further filters the model-layer data under the instruction of the data analysis request to retain, in the application-layer data, only the data to be displayed and applied. FIG. 4 is a screenshot of application-layer data in an embodiment. As shown in FIG. 4, the field settings of the application-layer data are the same as the items that need to be displayed and applied. Compared with the model-layer data, the content of the application-layer data is more concise and clear. For example, the fields are PRODUCT_ID (product No.), X and Y, etc. The operator can obtain the test result of the required item by going through the application-layer data.

The machine station file processing method realizes timely acquisition of the added and modified transaction files on the machine station server by monitoring the file system of the machine station server, avoiding low efficiency and easy file omissions when manually exporting data. Moreover, in this embodiment, the transaction files are sent to the edge computing server in an incremental synchronization manner, which improves the efficiency of file synchronization. Further, the edge computing server and the machine station server in this embodiment are both located in the FAB network segment. In this embodiment, data collection and initial processing are directly performed on the data side where the machine station server is located, and then the model-layer data initially processed by the edge computing server is sent to the data warehouse server in the OA network segment in real time, which solves the problems of low transmission speed and delay in processing that are easily caused by the excessive amount of machine station file data. Therefore, compared with the prior art, the machine station file processing method in this embodiment can automatically synchronize and warehouse transaction files and output structured model-layer data, thereby reducing the complexity of data analysis and improving the timeliness and accuracy of machine station file processing.

In an embodiment, the edge computing server comprises a file monitoring module, a file synchronization module, and a real-time warehousing module. FIG. 5 is a sub-flowchart of S100 in this embodiment. As shown in FIG. 5, the step S100 of the machinestation file processing method comprises S110 to S120.

S110: The file monitoring module is controlled to monitor the operation of a file system of a machine station server, and send a synchronization request to the file synchronization module.

Wherein, the file monitoring module is configured to monitor the addition and modification operations of the file system of the machine station server, and the file synchronization module is configured to synchronize the transaction files on the machine station server to the edge computing server.

Specifically, when the file monitoring module discovers the addition and modification operations of the file system, the file monitoring module immediately sends a synchronization request to the file synchronization module. The synchronization request is used to instruct the file synchronization module to synchronize the transaction files to the edge computing server for timely synchronization of the transaction files.

In an embodiment, the addition and modification operations of the file system of the machine station server are monitored by Inotify in Linux kernel. Inotify can monitor the set files and can also monitor the set directories or subdirectories, and issue related event warnings to the set programs or modules in time through the kernel. Therefore, in this embodiment, by Inotify, file monitoring that is more flexible, occupies less resource, and is more responsive is realized.

S120: The file synchronization module is controlled to receive the synchronization request, and call an incremental backup program to synchronize the transaction file; and when the synchronization of the transaction file is completed, send a warehousing instruction to the real-time warehousing module, the warehousing instruction being used to instruct the real-time warehousing module to convert the format of the transaction data according to preset warehousing rules.

Wherein, the incremental backup program is used for incremental backup of the transaction files. Incremental backup is a backup method to obtain the differential data between this backup and the previous backup. That is, after the first full backup, when the second incremental backup is performed, only the differential data between the second backup and the first backup is backed up; when the third incremental backup is performed, only the differential data between the third backup and the second backup is backed up; and so on. The real-time warehousing module is configured to warehouse the transaction data synchronized to the edge computing server to generate model-layer data.

Specifically, after the file synchronization module receives the synchronization request, the file synchronization module calls the incremental backup program to synchronize the transaction files. Compared with the full backup and the differential backup, the incremental backup requires less data to be backed up during each time of synchronization and is less time-consuming, and data occupies less space in the edge computing server, which is more suitable for the machine station file processing method in this embodiment. Moreover, the file control module can immediately send the warehousing instruction to the real-time warehousing module when the synchronization is completed. This can warehouse the transaction data in time, and effectively avoid the accumulation of transaction data caused by delay in processing.

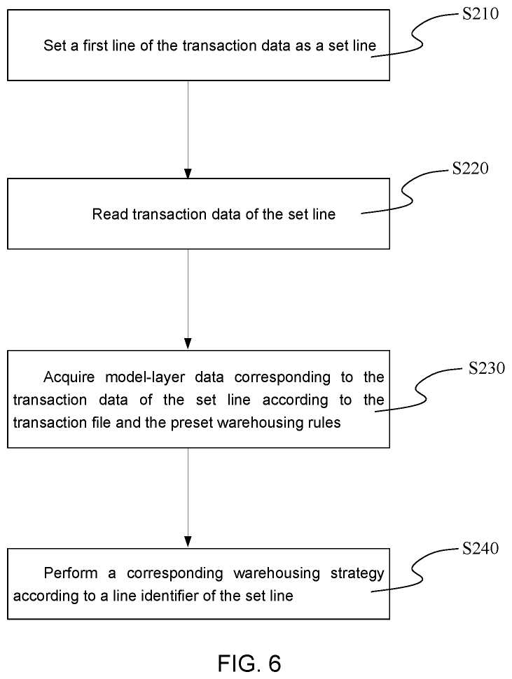

In an embodiment, the transaction file comprises at least one line of transaction data. FIG. 6 is a sub-flowchart of S200 in this embodiment. As shown in FIG. 6, the step S200 of the machine station file processing method comprises S210 to S240.

S210: The first line of the transaction data is set as a set line.

Specifically, since each line of transaction data contain different data formats and data volumes, it is unable to warehouse each line of the data in exactly the same way. Therefore, in this embodiment, set lines are warehoused one by one, by reading in lines. Further, in order to avoid the omission of transaction data, after acquiring the transaction file from a designate directory of the edge computing server, the real-time warehousing module in this embodiment starts reading and conversion from the first line of the transaction data, that is, sets the first line of the transaction data as a set line. For example, the first line in FIG. 2 is the line “0001, 20, 74, 1, 3, 767”.

S220: The transaction data of the set line is read.

S230: Model-layer data corresponding to the transaction data of the set line is acquired according to the transaction file and the preset warehousing rules.

Specifically, the preset warehousing rules comprise the conditions and methods for format conversion of the transaction data. Therefore, the content, which meets the format conversion conditions, in the transaction data can be imported into the set output position according to the set format conversion method and in a set output format, so as to acquire the model-layer data corresponding to the transaction data of the set line.

S240: A corresponding warehousing strategy is performed according to a line identifier of the set line.

Specifically, the transaction file usually comprises multiple lines of transaction data, and this embodiment supports warehousing by reading in lines. Therefore, it is necessary to traverse through each line of data in the transaction data by a set method. The warehousing strategy stipulates the logic and sequence of traversing through each line of transaction data. In this embodiment, by performing a corresponding warehousing strategy according to the line identifier, each line of transaction data can be acquired efficiently and completely.

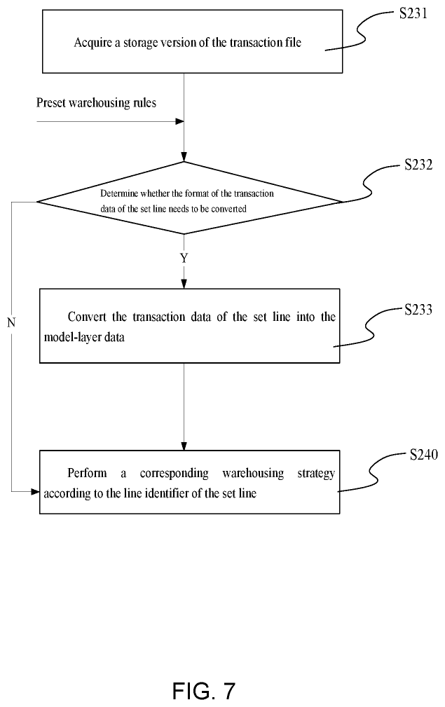

In an embodiment, as shown in FIG. 7, the step S230 of the machine station file processing method comprises S231 to S233.

S231: A storage version of the transaction file is acquired.

Specifically, transaction files of different types have different storage methods, and the storage versions of the transaction files are in one-to-one correspondence to the storage methods. Therefore, the storage methods of the transaction files may be acquired by acquiring their storage versions, so as to accurately warehouse the transaction data. This avoids format errors or content errors during the warehousing.

S232: It is determined, according to the storage version and the preset warehousing rules, whether the format of the transaction data of the set line needs to be converted.

Specifically, the preset warehousing rules have been set in the real-time warehousing module. The preset warehousing rules comprise information such as format conversion conditions and methods. Therefore, whether the format of data of the set line needs to be converted may be determined according to the conditions in the preset warehousing rules.

S233: The transaction data of the set line is converted into model-layer data, if the format of data of the set line needs to be converted.

If the format of data of the set line does not need to be converted, for example, the data of the set line in the transaction data is only used to record the test time of the wafer on the machine station, without involving information such as the wafer No. and test results. It is stipulated in the preset warehousing rules that the test time parameter is not warehoused, so there is no need to convert the transaction data of the set line into model-layer data. The process directly returns to S240 where a corresponding warehousing strategy is performed according to the line identifier of the set line.

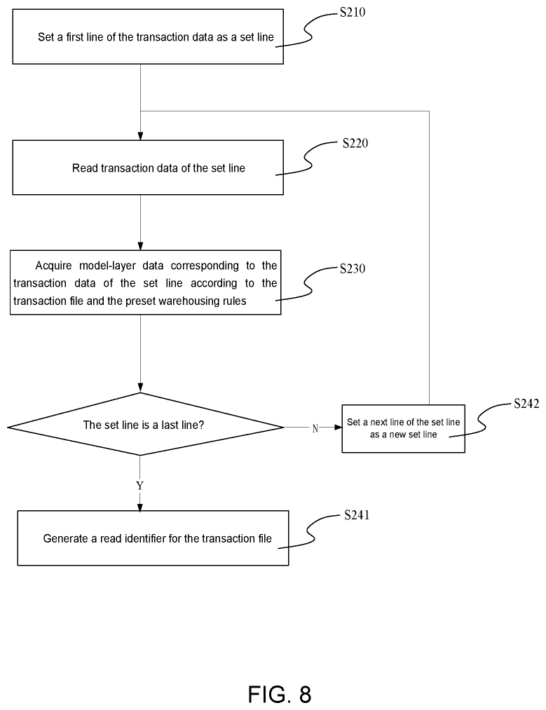

In an embodiment, as shown in FIG. 8, the step S240 of the machine station file processing method comprises S241 to S242.

S241: When the set line is the last line, a read identifier is generated for the transaction file.

Specifically, when the set line is the last line, it is indicated that the transaction data in the transaction file has been all read and warehoused. Then, the process jumps out of the loop of S220 to S230. Further, when the transaction file is successfully read and warehoused, by generating a read identifier for the transaction file, it is possible to prevent the repeated reading of files without any transaction by mistake, thereby improving the reliability of reading the files when they are warehoused in the machine station file processing method.

S242: When the set line is not the last line, the next line of the set line is set as a new set line, and the steps (S220 to S230) of reading the transaction data of the set line and acquiring model-layer data corresponding to the transaction data of the set line according to the transaction file and the preset warehousing rules are repeated until the new set line becomes the last line.

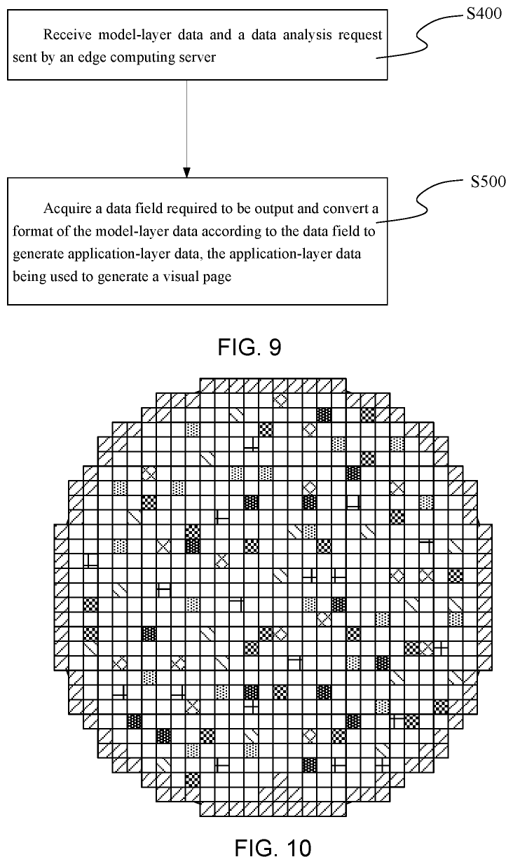

FIG. 9 is a flowchart of a machine station file processing method in an embodiment. The machine station file processing method in this embodiment is applied to a machine station file processing system. The machine station file processing system comprises a data warehouse server. As shown in FIG. 9, the machine station file processing method in this embodiment comprises S400 to S500.

S400: Model-layer data and a data analysis request sent by an edge computing server are received.

Specifically, the data warehouse server receives structured model-layer data, and responds to the data analysis request to acquire application-layer data according to the model-layer data.

S500: A data field required to be output is acquired and the format of the model-layer data is converted according to the data field to generate application-layer data, the application-layer data being used to generate a visual page.

The data fields required to be output are the data fields that need to be displayed and applied, that is, the data fields such as PRODUCT_ID, ROUTE_ID, X, Y, and CHIP_MAP shown in FIG. 4. The visual page is an intuitive graph or image that will be generated based on data. For example, scatter charts, pie charts, histograms, etc., are all visual pages. FIG. 10 shows a visual page of a wafer map commonly used in the field of semiconductors. The wafer map is used to intuitively show the distribution of qualified and defective grains in the wafer. The different filling methods in the wafer map may indicate the process or cause for the generation of defective grains.

Specifically, in this embodiment, the data field required to be output is acquired first, then the data required to be output is filtered from the model-layer data, and finally the application-layer data is acquired according to the filtered data. For example, in this embodiment, it is necessary to output the data in the data field “X”, and the test file generated by the machine station comprises the test data in both the field “A” and the field “B”. The data in the field “X” needs to be acquired by further analysis of the test data in the field “A” and the field “B”. Therefore, in this embodiment, the test data in the field “A” and the field “B” needs to be filtered from the model-layer data first, then the set data analysis is performed to obtain the data in the field “X”, and finally the data in the field “X” is saved in the application-layer data. It may be understood that, due to the enormous amount of wafer tests on a machine station, there is still a large amount of test data to be processed even in the stage of acquiring application-layer data. Therefore, in this embodiment, the application-layer data is automatically acquired according to the model-layer data and the data field required to be output. This can greatly reduce the complicated operation of acquiring the application-layer data manually, thereby improving the efficiency and reliability of acquiring the application-layer data.

Further, in this embodiment, in the process of acquiring the application-layer data, test data sheets in multiple different dimensions may be acquired based on the same actual test data, and the test data may be analyzed in multiple dimensions, thereby solving the problem that the analysis is not comprehensive enough since the data cannot be correlated for analysis.

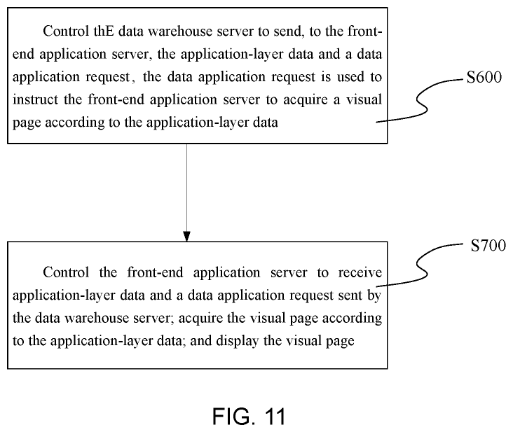

In an embodiment, the machine station file processing system further comprises a front-end application server. FIG. 11 is a flowchart of a machine station file processing method in this embodiment. As shown in FIG. 11, the machine station file processing method in this embodiment further comprises S600 to S700.

S600: The data warehouse server is controlled to send, to a front-end application server, the application-layer data and a data application request that is used to instruct the front-end application server to acquire a visual page according to the application-layer data.

Specifically, by sending the application-layer data and the data application request to the front-end application server, the front-end application server can be instructed to automatically acquire an appropriate visual page according to the application-layer data. Usually in the wafer data application stage, different visual pages need to be output for different data fields, so manual operations require complicated data selection and visual page type selection operations. In this embodiment, by the data application request, the front-end application server is instructed to automatically acquire a visual page, thereby improving the efficiency of data display and application.

S700: The front-end application server is controlled to receive application-layer data and a data application request sent by the data warehouse server; acquire the visual page according to the application-layer data; and display the visual page.

Specifically, the front-end application server receives the application-level data, and responds to the data application request, thereby quickly acquiring and displaying a visual page according to the application-layer data, which improves the speed of data display and application of the machine station file processing method. Wherein, the front-end application server may acquire the visual page by methods such as data analysis tools or front-end code development.

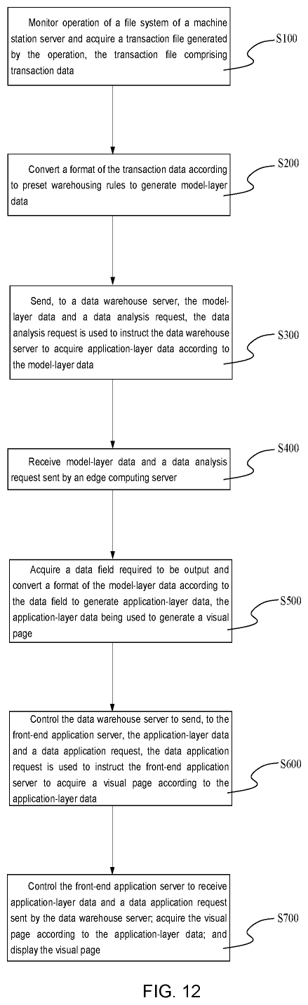

FIG. 12 is a machine station file processing method in an embodiment. As shown in FIG. 12, the machine station file processing method in this embodiment comprises S100 to S700. The machine station file processing method in this embodiment realizes timely acquisition of the added and modified files on the machine station server by monitoring the file system of the machine station server, avoiding low efficiency and easy file omissions when manually exporting data. Moreover, in this embodiment, the transaction files are sent to the edge computing server in an incremental synchronization manner, which improves the efficiency of file synchronization. Further, the edge computing server and the machine station server in this embodiment are both located in the FAB network segment. In this embodiment, data collection and initial processing are directly performed on the data side where the machine station server is located, and then the model-layer data initially processed by the edge computing server is sent to the data warehouse server in the OA network segment in real time, which solves the problems of low transmission speed and delay in processing that are easily caused by the excessive amount of machine station file data. After the model-layer data is acquired, in this embodiment, the application-layer data is acquired automatically by the data warehouse server, and a visual page is automatically acquired and displayed by the front-end application server. Thus, faster data display and application is realized. Therefore, from test file generation, data collection, data analysis to visual page display, this embodiment realizes a completely automatic data processing process, so the method in this embodiment is a machine station file processing method with both timeliness and reliability.

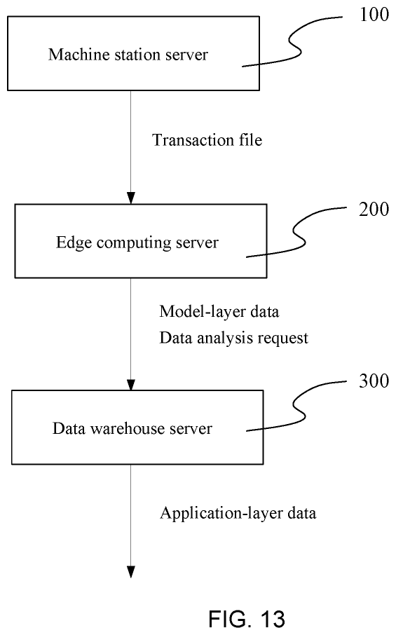

FIG. 13 is a schematic structure diagram of a machine station file processing system in an embodiment. As shown in FIG. 13, the machine station file processing system comprises a machine station server 100, an edge computing server 200, and a data warehouse server 300.

The machine station server 100 is configured to perform file system operations and generate a transaction file.

The edge computing server 200 is configured to: monitor the operation of the file system of the machine station server 100 and acquire a transaction file generated by the operation; the edge computing server convert the format of the transaction data according to preset warehousing rules to generate model-layer data; and send, to the data warehouse server 300, the model-layer data and a data analysis request that is used to instruct the data warehouse server 300 to acquire application-layer data according to the model-layer data.

The data warehouse server 300 is configured to: receive model-layer data and a data analysis request sent by the edge computing server 200; and acquire a data field required to be output and convert the format of the model-layer data according to the data field to generate application-layer data, the application-layer data being used to generate a visual page.

The machine station file processing system in this embodiment acquires the added and modified transaction files on the machine station server 100 in time by the edge computing server 200, and converts the transaction data into structured model-layer data on the data side, and then converts the model-layer data into application-layer data by the data warehouse server 300,thereby realizing fast acquisition and analysis of test files.

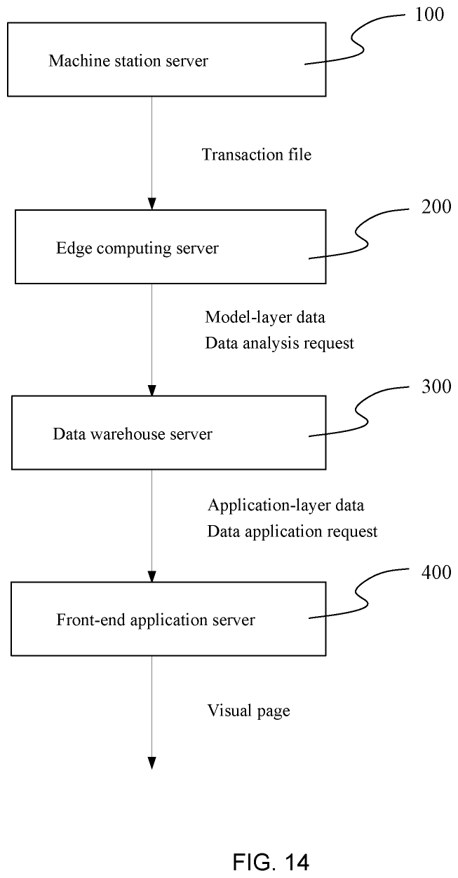

FIG. 14 is a schematic structure diagram of a machine station file processing system in an embodiment. As shown in FIG. 14, the data warehouse server 300 is further configured to send, to the front-end application server 400, the application-layer data and a data application request that is used to instruct the front-end application server 400 to acquire a visual page according to the application-layer data. The machine station file processing system further comprises a front-end application server 400 configured to: receive application-layer data and a data application request sent by the data warehouse server 300; acquire the visual page according to the application-layer data; and display the visual page. The machine station file processing system in this embodiment realizes automatic visualization of test data by the front-end application server 400, thereby improving the efficiency of data display and application.

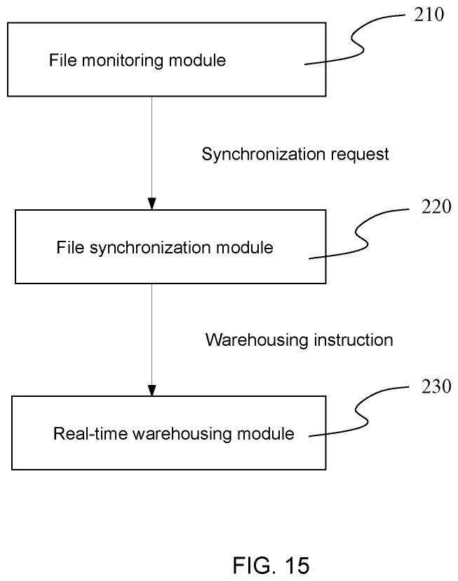

FIG. 15 is a schematic structure diagram of an edge computing server 200 in an embodiment. As shown in FIG. 15, the edge computing server 200 comprises: a file monitoring module 210, a file synchronization module 220 and a real-time warehousing module 230.

The file monitoring module 210 is configured to monitor the operation of a file system of a machine station server 100, and send a synchronization request to the file synchronization module 220.

The file synchronization module 220 is configured to: receive the synchronization request, and call an incremental backup program to synchronize the transaction file; and when the synchronization of the transaction file is completed, send a warehousing instruction to the real-time warehousing module 230, the warehousing instruction being used to instruct the real-time warehousing module 230 to convert the format of the transaction data according to preset warehousing rules.

The real-time warehousing module 230 is configured to: convert the format of the transaction data according to preset warehousing rules to generate model-layer data; and send, to a data warehouse server 300, the model-layer data and a data analysis request that is used to instruct the data warehouse server 300 to acquire application-layer data according to the model-layer data.

Through the cooperation of the file monitoring module 210, the file synchronization module 220 and the real-time warehousing module 230, the edge computing server 200 in this embodiment realizes the automatic incremental synchronization of transaction files and the automatic warehousing of transaction data, thereby effectively avoiding the accumulation of transaction data caused by delay in processing, and thus improving the operational reliability of the machine station file processing system.

Various technical features of the above embodiments can be arbitrarily combined. For simplicity, all possible combinations of various technical features of the above embodiments are not described. However, all those technical features shall be included in the protection scope of the present disclosure if not conflict.

The embodiments described above merely represent certain implementations of the present disclosure. Although those embodiments are described in more specific details, it is not to be construed as any limitation to the scope of the present disclosure. It should be noted that, for a person of ordinary skill in the art, a number of variations and improvements may be made without departing from the concept of the present disclosure, and those variations and improvements should be regarded as falling into the protection scope of the present disclosure. Therefore, the protection scope of the present disclosure should be subject to the appended claims.

1. A machine station file processing method, applied to an edge computing server, comprising:
monitoring operation of a file system of a machine station server and acquiring a transaction file generated by the operation, the transaction file comprising transaction data;
converting a format of the transaction data according to preset warehousing rules to generate model-layer data; and
sending, to a data warehouse server, the model-layer data and a data analysis request, the data analysis request is used to instruct the data warehouse server to acquire application-layer data according to the model-layer data.

2. The machine station file processing method according to claim 1, wherein the edge computing server comprises a file monitoring module, a file synchronization module and a real-time warehousing module; and the monitoring operation of a file system of a machine station server and acquiring a transaction file generated by the operation comprises:
controlling the file monitoring module to monitor the operation of the file system of the machine station server, and sending a synchronization request to the file synchronization module; and
controlling the file synchronization module to receive the synchronization request, and calling an incremental backup program to synchronize the transaction file; and when the synchronization of the transaction file is completed, sending a warehousing instruction to the real-time warehousing module, the warehousing instruction being used to instruct the real-time warehousing module to convert the format of the transaction data according to the preset warehousing rules.

3. The machine station file processing method according to claim 1, wherein the transaction file comprises at least one line of transaction data; and the converting a format of the transaction data according to preset warehousing rules to generate model-layer data comprises:
setting a first line of the transaction data as a set line;
reading transaction data of the set line;
acquiring model-layer data corresponding to the transaction data of the set line according to the transaction file and the preset warehousing rules; and
performing a corresponding warehousing strategy according to a line identifier of the set line.

4. The machine station file processing method according to claim 3, wherein the performing a corresponding warehousing strategy according to a line identifier of the set line comprises:
when the set line is a last line, generating a read identifier for the transaction file; and
when the set line is not the last line, setting a next line of the set line as a new set line, and repeating steps of reading the transaction data of the set line and acquiring model-layer data corresponding to the transaction data of the set line according to the transaction file and the preset warehousing rules until the new set line becomes the last line.

5. The machine station file processing method according to claim 3, wherein the acquiring model-layer data corresponding to the transaction data of the set line according to the transaction file and the preset warehousing rules comprises:
acquiring a storage version of the transaction file;
determining, according to the storage version and the preset warehousing rules, whether the format of the transaction data of the set line needs to be converted;
converting the transaction data of the set line into the model-layer data, if the format of the transaction data of the set line needs to be converted; and
directly returning to step of performing a corresponding warehousing strategy according to the line identifier of the set line, if the format of the transaction data of the set line does not need to be converted.

6. The machine station file processing method according to claim 1, wherein the monitoring operation of a file system of a machine station server comprises:
monitoring addition and modification operations of the file system of the machine station server by Inotify in Linux kernel.

7. The machine station file processing method according to claim 1, wherein the sending, to the data warehouse server, the model-layer data and the data analysis request and the data analysis request is used to instruct the data warehouse server to acquire application-layer data according to the model-layer data comprises:
synchronously sending, by the edge computing server, generated model-layer data and the data analysis request to the data warehouse server, and further filtering, by the data warehouse server, the model-layer data under the instruction of the data analysis request to retain, in the application-layer data, only the data to be displayed and applied.

8. The machine station file processing method according to claim 2, wherein, after acquiring the transaction file from a designate directory of the edge computing server, the real-time warehousing module starts reading and conversion from a first line of the transaction data, that is, sets the first line of the transaction data as a set line.

9. A machine station file processing method, applied to a machine station file processing system comprising a data warehouse server, the machine station file processing method comprises: controlling the data warehouse server to:
receive model-layer data and a data analysis request sent by an edge computing server; and
acquire a data field required to be output and convert a format of the model-layer data according to the data field to generate application-layer data, the application-layer data being used to generate a visual page.

10. The machine station file processing method according to claim 9, wherein the machine station file processing system further comprises a front-end application server; and the machine station file processing method further comprises:
controlling the data warehouse server to send, to the front-end application server, the application-layer data and a data application request, the data application request is used to instruct the front-end application server to acquire a visual page according to the application-layer data; and
controlling the front-end application server to receive application-layer data and a data application request sent by the data warehouse server; acquiring the visual page according to the application-layer data; and displaying the visual page.

11. The machine station file processing method according to claim 9, wherein the data field required to be output is acquired first, then the data required to be output is filtered from the model-layer data, and finally the application-layer data is acquired according to the filtered data.

12. A machine station file processing system, comprising:
an edge computing server, configured to monitor operation of a file system of a machine station server and acquire a transaction file generated by the operation; convert a format of the transaction data according to preset warehousing rules, to generate model-layer data; and send, to a data warehouse server, the model-layer data and a data analysis request, the data analysis request is used to instruct the data warehouse server to acquire application-layer data according to the model-layer data; and
a data warehouse server, configured to receive the model-layer data and the data analysis request sent by an edge computing server; and acquire a data field required to be output and convert the format of the model-layer data according to the data field to generate the application-layer data.

13. The machine station file processing system according to claim 12, wherein the data warehouse server is further configured to send, to a front-end application server, the application-layer data and a data application request, the data application request is used to instruct the front-end application server to acquire a visual page according to the application-layer data; and the machine station file processing system further comprises:
a front-end application server, configured to receive the application-layer data and the data application request sent by the data warehouse server; acquire a visual page according to the application-layer data; and display the visual page.

14. The machine station file processing system according to claim 12, wherein the edge computing server comprises:
a file monitoring module, configured to monitor the operation of the file system of the machine station server, and send a synchronization request to a file synchronization module;
the file synchronization module, configured to receive the synchronization request, and call an incremental backup program to synchronize a transaction file; and when the synchronization of the transaction file is completed, send a warehousing instruction to a real-time warehousing module, the warehousing instruction being used to instruct the real-time warehousing module to convert a format of the transaction data according to preset warehousing rules; and
the real-time warehousing module, configured to convert the format of the transaction data according to preset warehousing rules to generate model-layer data; and send, to a data warehouse server, the model-layer data and a data analysis request, the data analysis request is used to instruct the data warehouse server to acquire application-layer data according to the model-layer data.

15. The machine station file processing method according to claim 4, wherein the acquiring model-layer data corresponding to the transaction data of the set line according to the transaction file and the preset warehousing rules comprises:
acquiring a storage version of the transaction file;
determining, according to the storage version and the preset warehousing rules, whether the format of the transaction data of the set line needs to be converted;
converting the transaction data of the set line into the model-layer data, if the format of the transaction data of the set line needs to be converted; and
directly returning to step of performing a corresponding warehousing strategy according to the line identifier of the set line, if the format of the transaction data of the set line does not need to be converted.

16. The machine station file processing system according to claim 13, wherein the edge computing server comprises:
a file monitoring module, configured to monitor operation of the file system of the machine station server, and send a synchronization request to a file synchronization module;
the file synchronization module, configured to receive the synchronization request, and call an incremental backup program to synchronize a transaction file; and when the synchronization of the transaction file is completed, send a warehousing instruction to a real-time warehousing module, the warehousing instruction being used to instruct the real-time warehousing module to convert a format of the transaction data according to preset warehousing rules; and
the real-time warehousing module, configured to convert the format of the transaction data according to preset warehousing rules to generate model-layer data; and send, to a data warehouse server, the model-layer data and a data analysis request, the data analysis request is used to instruct the data warehouse server to acquire application-layer data according to the model-layer data.
